(19) United States
(12) Patent Application Publication
(10) Pub. No.: US 2012/0098114 A1
(43) Pub. Date: Apr. 26, 2012

(54) Device with mold cap and method thereof

(75) Inventor: Kazuo Ishibashi, Tokyo (JP)

(73) Assignee: Nokia Corporation

(21) Appl. No.: 12/925,487

(22) Filed: Oct. 21, 2010

(51) Int. Cl. H01L 23/538; H01L 21/50

(52) U.S. Cl. 257/686; 257/692; 438/107; 257/E23.169; 257/E21.499

(57) ABSTRACT

A device including a substrate; at least one semiconductor die on a first side of the substrate; and a mold cap molded on portions of the first side of the substrate and on lateral sides of the at least one semiconductor die. The mold cap is not molded onto a top side of the at least one semiconductor die.

### BACKGROUND OF THE INVENTION

1. Field of the Invention

The invention relates to a semiconductor device and, more particularly, to a device having a mold cap around a silicon die.

2. Background

A die in the context of integrated circuits is a small block of semiconducting material, on which a given functional circuit is fabricated. In electronic engineering, a through-silicon via (TSV) is a vertical electrical connection (via) passing completely through a silicon wafer or die. TSV technology is important in creating 3D packages and 3D integrated circuits.

A three dimensional integrated circuit (3D IC) is a single integrated circuit built by stacking silicon wafers and/or dies and interconnecting them vertically so that they behave as a single device. By using TSV technology, 3D ICs can pack a great deal of functionality into a small “footprint.” In addition, critical electrical paths through the device can be drastically shortened, leading to faster operation.

A 3D package (System in Package, Chip Stack, Multi-Chip Modules (MCM), etc.) contains two or more chips (integrated circuits) stacked vertically so that they occupy less space. An alternate type of 3D package comprises ICs which are not stacked, but a carrier substrate containing TSVs is used to connect multiple ICs together in a package. In most 3D packages, the stacked chips are wired together along their edges. This edge wiring increases the length and width of the package and usually requires an extra “interposer” layer between the chips. In some new 3D packages, through-silicon vias replace edge wiring by creating, vertical connections through the body of the chips. The resulting package has no added length or width. Because no interposer is required, a TSV 3D package can also be flatter than an edge-wired 3D package. This TSV technique is sometimes also referred to as TSS (Through-Silicon Stacking or Thru-Silicon Stacking).

### SUMMARY

The following summary is merely intended to be exemplary. The summary is not intended to limit the scope of the claimed invention.

In accordance with one aspect of the invention, a device is provided including a substrate; at least one semiconductor die on a first side of the substrate; and a mold cap molded on portions of the first side of the substrate and on lateral sides of the at least one semiconductor die. The mold cap is not molded onto a top side of the at least one semiconductor die.

In accordance with another aspect of the invention, a method is provided comprising connecting at least one semiconductor die onto a first side of a substrate; after the at least one semiconductor die has been connected to the first side of the substrate, molding a cap onto portions of both the first side of the substrate and lateral sides of the at least one semiconductor die, the cap not extending above a top side of the at least one semiconductor die.

### BRIEF DESCRIPTION OF THE DRAWINGS

The foregoing aspects and other features of the invention are explained in the following description, taken in connection with the accompanying drawings, wherein:

FIG. 1 is a schematic partial cross sectional view of an example embodiment of the invention;

FIG. 2 is a perspective view of an apparatus comprising the device shown in FIG. 1;

FIG. 3 is a schematic partial cross sectional view of the device shown in FIG. 1 before the mold cap is overmolded onto the device;

FIG. 4 is a perspective view of the mold cap shown in FIG. 1;

FIG. 5 is a block diagram illustrating features of one example method of the invention;

FIG. 6 is a schematic partial cross sectional view of a package comprising the device shown in FIG. 1;

FIG. 7 is a schematic partial cross sectional view of an alternative package comprising the device shown in FIG. 1; and

FIG. 8 is a schematic partial cross sectional view of an alternative embodiment of the device shown in FIG. 1.

### DETAILED DESCRIPTION OF EMBODIMENTS

Although the invention will be described with reference to the example embodiments shown in the drawings, it should be understood that the invention may be embodied in many alternate forms of embodiments. In addition, any suitable size, shape or type of elements or materials could be used.

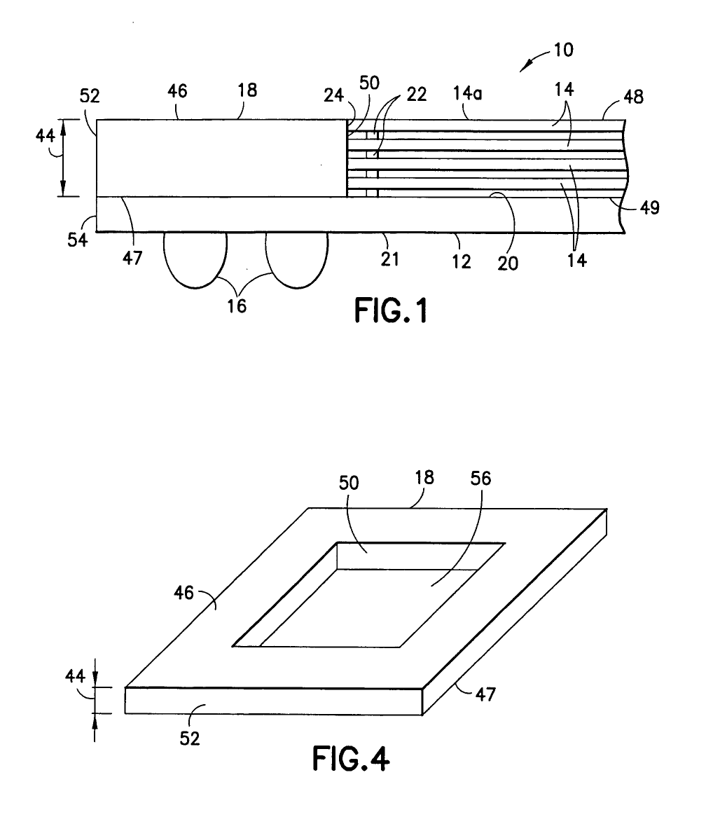

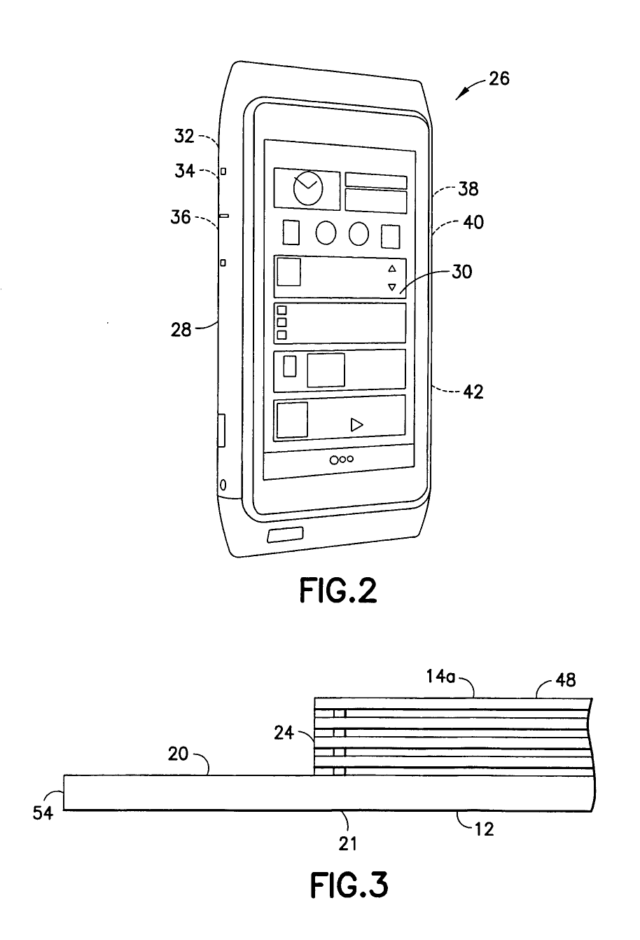

Referring to FIG. 1, there is shown a schematic partial cross sectional view of a device 10 according to an example embodiment of the invention. The device 10 is an electronic component for use in an electronic apparatus. An example of an electronic apparatus 26 having the device 10 is shown in FIG. 2. In this example the apparatus 26 is a hand-held portable apparatus comprising various features including a telephone application, Internet browser application, camera application, video recorder application, music player and recorder application, email application, navigation application, gaming application, and/or any other suitable electronic device application. The apparatus 26, in this example embodiment, comprises a housing 28, a touch screen 30 which functions as both a display and a user input, a receiver 32, a transmitter 34, a rechargeable battery 42, and a controller 36 which may include at least one processor 38, at least one memory 40, and software. The device 10 may be used as, for example, a memory in the apparatus 26 or a application-specific integrated circuit (ASIC) in the apparatus 26. The apparatus 26 is merely shown as an example of an apparatus in which the device 10 could be used, and this example should not be considered as limiting the invention.

Referring back to FIG. 1, the device 10 in this example embodiment comprises a substrate 12, semiconductor dies 14, fusible elements 16, and a mold cap 18. Additional features or elements could be provided. The substrate 12 comprises a printed wiring board type of substrate which is configured to electrically connect the dies 14 to the fusible elements 16. The semiconductor dies 14 comprise a plurality of dies stacked together as a 3D integrated circuit (IC) 14a. However, in an alternate embodiment the device 10 might comprise only one semiconductor die, or the dies might not be stacked exactly as shown. In this example embodiment the dies 14 are interconnected vertically by conductors 22 (passing completely through the dies) so that they behave as a single device. By using through-silicon via (TSV) technology, the 3D IC 14a formed by the dies 14 can pack a great deal of functionality into a small “footprint” or area on the side 20 of the substrate 12. In addition, critical electrical paths 22 through the IC 14a can be drastically shortened, leading to faster operation. In an alternate embodiment a connection of the dies 14 other than a TSV connection might be used. In the example embodiment shown the IC 14a is flip-chip mounted directly on the first side 20 of the substrate 12.

The fusible elements 16 comprise solder balls in this embodiment. However, in alternate embodiments any suitable type of fusible element could be provided. The fusible elements are attached to the second side 21 of the substrate opposite the first side 20. The fusible elements can be melted and subsequently allowed to cool to mechanically and electrically connect the device 10 to another member (not shown). Alternatively, or additionally, a different type of electrical connection to the other member could be provided, such as a through hole contact or surface contact for example.

The mold cap 18 comprises molded plastic or polymer material which is overmolded onto the first side 20 of the substrate and onto the lateral sides 24 of the IC 14a at the same time. Referring also to FIG. 3 the device is shown before the mold cap 18 is formed. As can be seen, the IC 14a is attached to the substrate 12 before the mold cap 18 is formed. The fusible elements 16 could be attached to the substrate 12 before or after the mold cap 18 is formed. FIG. 4 shows the mold cap 18 after the mold cap is formed, but without showing the other components of the device 10 merely for the sake of clarity. The mold cap 18 is not formed separately from the device 10. Instead, the mold cap 18 must be overmolded onto the first side 20 of the substrate and onto the lateral sides 24 of the IC 14a.

“Overmolding” is a specific type of injection molding; not merely any type of molding. The substrate 12 with the IC 14a attached can be positioned into a mold (not shown), material is injected into the mold, and the mold cap 18 is thus overmolded onto the two members 12, 14a inside the mold. When the substrate 12 and IC 14a are located in the mold, part of the mold contacts and covers the top side 48 of the IC 14a so the mold cap 18 is prevented from forming on the top side 48. Sides of the mold allow the mold cap 18 to be overmolded all the way up to and even with the lateral sides 54 of the substrate 12. In alternate embodiments the sides 52 might not be even with the sides 54, and a molding process other than overmolding could be used. The mold cap 18 might be overmolded onto the IC 14a, and then the mold cap 18 and IC 14a could be attached to the substrate 12.

When the mold cap 18 is overmolded onto the surface 20 and sides 24, the molded material bonds onto the surfaces 20, 24 and subsequently hardens such that the mold cap mechanically strengthens the substrate 12 and mechanically strengthens connection of the IC 14a with the substrate 12 forming a unitary structure. The inner facing surface 50 (see FIG. 4) of the mold cap 18 is located only around a side perimeter of the IC 14a. The outer lateral or perimeter sides 52 could extend to the outer lateral or perimeter sides 54 of the substrate. Thus, with a square or rectangular shaped substrate and a square or rectangular shaped IC 14a, the mold cap 18 may have a general picture frame shape with a channel 56 entirely through the mold cap 18 between its top side 46 and its bottom side 47. The IC 14a is located in that channel 56; preferably occupy the entire channel 56.

In the embodiment shown in FIG. 1 the height 44 of the mold cap 18 is about the same height as the IC 14a on the substrate 12. It is desired to not have the top surface 46 of the mold cap 18 extend above the top surface 48 of the IC 14a. FIG. 8 shows an alternate embodiment where the mold cap 18′ has a height 44′ less than the height of the IC 14a. Thus, the top surface 46′ is lower than the top side 48 of the IC 14a. The height of the mold cap is preferably equal to or less than the height of the IC on the substrate. Thus, none of the material of the mold cap 18 extends above the top side 48 of the IC. No portion of the mold cap 18 is located on the top side 48. The top side 48 of the IC is the highest portion of the device measured from the substrate 12. In one type of example embodiment the mold cap 18 does not extend between the IC 14a and the substrate. However, with another type of example embodiment Molded Under-Fill (MUF) could be used which can both overmold and may have mold under-filling take place at the same time.

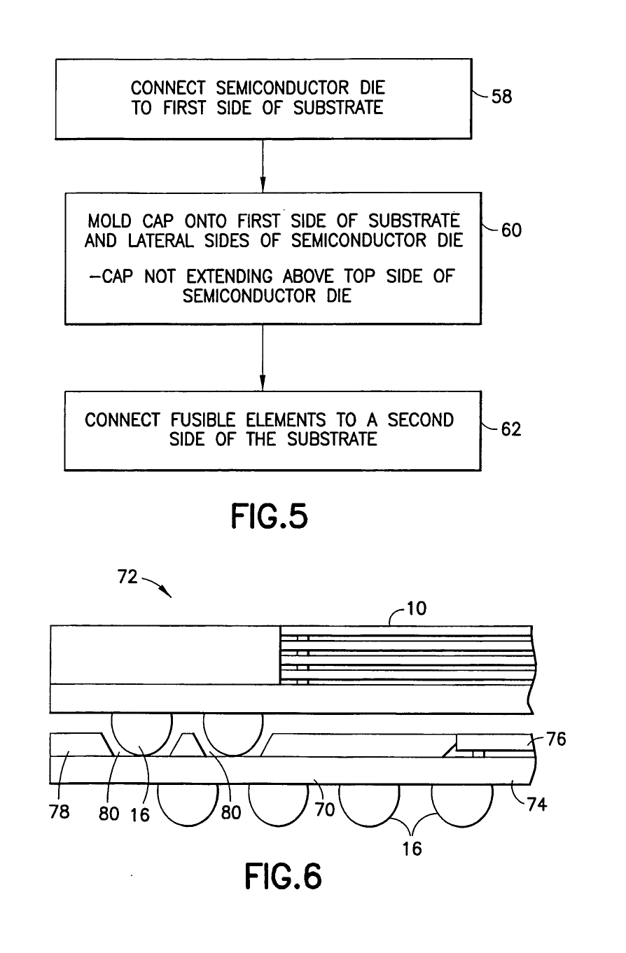

Referring also to FIG. 5, in one method of the invention at least one semiconductor die 14 is attached to the substrate 12 as indicated by block 58. As indicated by block 60, the mold cap 18 is overmolded onto the first side 20 and at the lateral sides 24 of the die(s) 14, but not extending above the top side 48 of the top dies of the stack 14a. The fusible elements 16 are connected to the substrate's second side 21 as indicated by block 62. As noted above the fusible elements 16 could be attached after the mold cap 18 is formed, but the die(s) 14 must be attached to the substrate 12 before the mold cap 18 is formed. The resultant device 10 forms a Ball Grid Array (BGA) IC device.

Ball Grid Array (BGA) IC packaging is widely used for mobile applications. Miniaturization is a main driver for the packaging, and thickness or height reduction is especially important in order to realize thinner mobile phone products. Suppliers have been working hard to make memory and ASIC packages as thin as possible without sacrificing quality and reliability. Reduction of every 10 microns in thickness makes sense to make the package thinner as much as possible. Naturally thickness reduction must be realized without sacrificing device quality and reliability, such as package warpage (which could cause soldering problem) or mechanical strength.

There are two major mobile applications for BGA IC packaging: Memory and ASIC. In a typical memory BGA package, multiple memory dies are wire-bonded and stacked with each other on an organic substrate with a plastic mold cap for protection. A desire for thickness reduction is naturally more demanding in Package-on-Package (PoP) BGA than in stand-alone BGA. An ASIC die is usually flip-chip attached without a mold cap. This type of bare-die flip-chip package often exhibits large package warpage at elevated temperature during soldering process and could cause yield-loss problem. Use of a thicker substrate is effective to reduce package warpage, but it increases PoP stack-up thickness at the same time; so it is not a preferred way. One example embodiment of the present invention may be used in a Ball Grid Array (BGA) package. The idea can comprise a mold cap only around a die or die stack so that the top surface of the die is exposed. The highest vertical level of the mold cap can be the same as or lower than the top surface of the die or die stack.

One technical challenge which the invention addresses is to reduce the thickness of a Package-on-Package (PoP) assembly. An example embodiment of the invention may comprise a package structure of a partial mold cap with an exposed flip-chip die. As used herein, “partial mold cap” merely means that the mold cap is not located over the top side of the die. If applied to a TSV-stacked memory, the invention can decrease package thickness by the amount a mold cap 18 would otherwise extend over the die. If applied to a TSV PoP with silicon substrate it reinforces the mechanical strength of the substrate and improves reliability, without increasing stack-up thickness (height).

Referring also to FIG. 6, the device 10 is shown in conjunction with a second device 70 to form a package or assembly 72. The second device 70 comprises a silicon substrate 74, a semiconductor die 76, a mold cap 78 and fusible elements 16. The die 76 is connected with Through-Silicon Via (TSV) connections to the second substrate 74. For a single die flip-chip application, a TSV connection might not be provided. Instead, flip-chip solder bumps might be provided on the functional surface of the die (the surface facing the substrate). In this embodiment the mold cap 78 has a top surface which is located at or below the top surface of the die 76. The mold cap 78 comprises Through-Mold Vias (TMV) 80 which allow access to the contact areas on the top side of the substrate 74 for the fusible elements 16 of the device 10. By use of a TMV technique, where the vias 80 are formed such as by laser-drilling the vias 80 into the mold cap for example, this can increase the area of the mold cap on the substrate 74. In the example embodiment shown, with use of a TMV technique the area of the mold cap on the substrate 74 can be extended all the way to the outer edges of the substrate 74. The thin silicon substrate 74 is fragile and may not have enough mechanical strength by itself (i.e. the silicon substrate could crack in reliability testing such as drop testing and temperature cycling testing). Use of the mold cap 78 on the top surface of the substrate 74 around the die(s) makes the assembly 74/78 less fragile and improves mechanical strength without having to use a thicker silicon substrate to improve mechanical strength; which would otherwise increase PoP stack-up thickness.

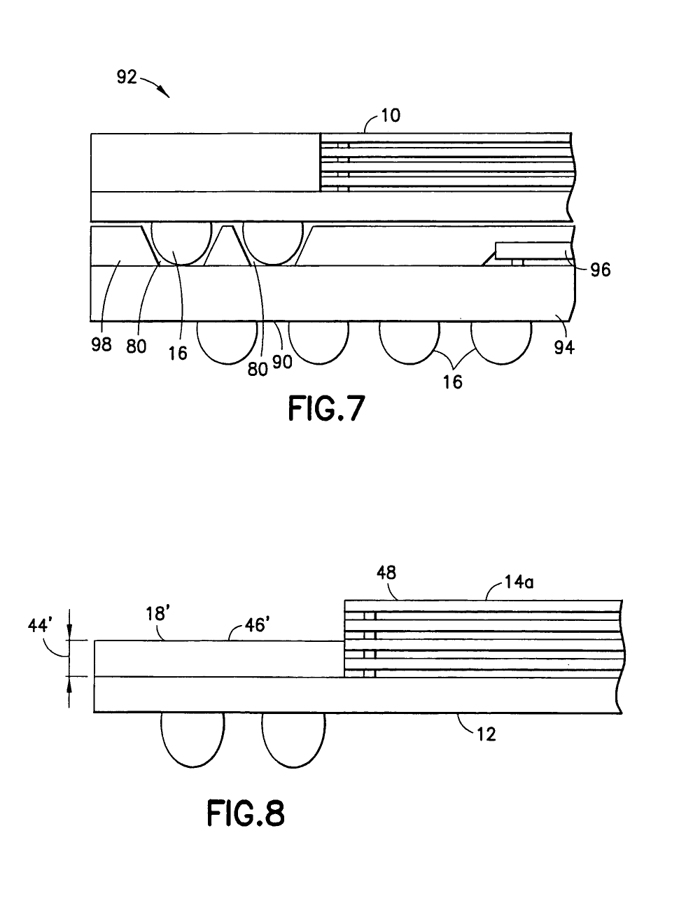

Referring also to FIG. 7, the device 10 is shown in conjunction with a second device 90 to form a package or assembly 92. The second device 90 comprises an organic (non-silicon) substrate 94, a semiconductor die 96, a mold cap 98 and fusible elements 16. In this embodiment the mold cap 98 has a top surface which is located above the top surface of the die 96. The mold cap 98 comprises Through-Mold Vias (TMV) 80 which allow access to the contact areas on the top side of the substrate 94 for the fusible elements 16 of the device 10. By use of a TMV technique where the vias 80 are formed, such as by laser-drilling the vias 80 into the mold cap for example, the increased area of the mold cap on the substrate 94 can reduce warpage of the substrate.

With an example embodiment of the invention, the new packaging “TSV-stacked” memory technology may be used where very thin multiple dies with TSV (Through-Silicon Via) are, stacked and interconnected with each other, flip-chip mounted on an organic substrate and then have an overmolded cap formed. Total thickness of the TSV-stacked memory is much thinner than wire-bonded memory for a same die count.

Thickness reduction is naturally more demanding in PoP (package on package) BGA than in standalone BGA. In the past an ASIC die was usually flip-chip attached without a mold cap. This type of bare-die flip-chip package often exhibits large package warpage at elevated temperature during soldering process and could cause yield-loss problem. Use of a thicker substrate is effective to reduce package warpage, but it increases PoP stack-up thickness at the same time so it's not a preferred way. With the invention, TMV (through-mold via) PoP technology may be used which has a mold cap to compensate for or reduce package warpage. The mold cap may have laser-drilled TMV 80 to interconnect, for example, a memory BGA on top.

FIG. 6 shows an example embodiment for illustrating thickness reduction of PoP. In this example a TSV PoP bottom package may be provided which uses a very thin silicon substrate with TSV (through silicon via). TSV-stacked memory device 10 may be used as a top package to make overall stack height very small. TSV PoP also has an advantage of small package warpage because both the die 76 and the substrate 74 are made of silicon so mismatch of thermal expansion can be minimized. Bare-die 76 height and mold cap 78 height of the ASIC package do not directly affect total PoP 72 stack height. What affects the PoP 72 stack height is the distance from the summit of the solder ball 16 of the ASIC 70 to the top-side ball pad of the ASIC 70 at 80. Naturally, however, the bare-die 76 height and the mold cap 78 height should be lower than the height of the solder ball of the memory 10 in order to make the memory-ASIC interconnection possible.

In PoP ASIC packaging, TSV package is quite effective to make PoP stack-up thickness very thin. The problem of a thin silicon substrate being fragile and not having enough mechanical strength is overcome by use of a mold cap. With an example embodiment of the invention, a mold cap, whose X, Y dimension sizes are about the same as a package (such as about 12×12 mm for example) may surround a die (such as about 10×9 mm for example) similar to a picture frame. This way the package thickness or height becomes only as high as the die and no higher. Thus, compared to an equivalent package where the mold cap covers the top surface of the die, a package comprising the invention is less high because there is no mold cap thickness above the top surface of the die.

As seen in FIG. 6 the invention may be applied to a PoP TSV package on a bottom side. In this example the device 70 forms the PoP TSV package on the bottom side. The device 70 may have a TMV mold cap 78, but the top surface of the die 76 may be exposed. This way the mold cap 78 reinforces the mechanical strength of silicon substrate 74 and improves package reliability. From a thickness viewpoint, in this case, the TMV mold cap 78 may be a little bit thicker and cover the die top surface (such as seen in FIG. 7) without sacrificing PoP stackup thickness. However, organic molding material increases package warpage for this silicon substrate package. Therefore, the thickness of a TMV mold is preferably small as much as possible, as long as it provides enough mechanical reinforcement. For a TSV-stacked memory package, the invention can reduce package thickness by the amount of mold cap thickness would otherwise occupy above a die. For a PoP ASIC package with a TSV silicon substrate, the invention can reinforce the mechanical strength of the silicon substrate and improve mechanical reliability, without sacrificing PoP stack-up thickness.

With an example embodiment of the invention, a device 10 may be provided comprising a substrate 12; at least one semiconductor die 14 connected directly on a first side 20 of the substrate; fusible elements 16 on a second side 21 of the substrate; and a mold cap 18 overmolded onto portions of the first side of the substrate and on lateral sides 24 of the at least one semiconductor die, where the mold cap is not molded onto a top side 48 of the at least one semiconductor die. The at least one semiconductor die may comprise a plurality of semiconductor dies connected in a stack. The semiconductor dies may comprise through-silicon via (TSV) connections. A top end 46 of the mold cap may be below the top side 48 of the at least one semiconductor die. The mold cap may have a general square or rectangular shape. The mold cap may have an inner facing surface 50 located only around a side perimeter of the at least one semiconductor die.

The device 10 may be provided as a first device in a package 72, 92 having a second device 70, 90 wherein the second device comprises a second substrate 74, 94; at least one second semiconductor die 76, 96 on a first side of the second substrate; second fusible elements 16 on a second side of the second substrate; and a second mold cap 78, 98 on the first side of the second substrate and on lateral sides of the at least one second semiconductor die, where the fusible elements 16 of the first device 10 are connected to the second device 70, 90 at the first side of the second substrate.

The fusible elements of the first device may extend through through-mold vias (TMV) in the second mold cap. The second mold cap may not be molded onto a top side of the at least one second semiconductor die. The at least one second semiconductor die 76, 96 may comprise a plurality of second semiconductor dies connected in a stack. The second semiconductor die(s) 76, 96 may comprise through-silicon via (TSV) connections. A top end of the second mold cap 78 may be below a top side of the at least one second semiconductor die 76. A top end of the second mold cap 98 may be above a top side of the at least one second semiconductor die 96. The second mold cap may have a general square or rectangular shape. The second mold cap may have a top face, a bottom face and an inner facing surface located between the top and bottom faces and located only around a side perimeter of the at least one second semiconductor die. The second substrate 74 may comprise silicon substrate, and the second mold cap 78 may be located over substantially the entire first side of the silicon substrate 74 excluding an area of the silicon substrate having the at least one semiconductor die 76 thereon.

A method may be provided comprising connecting 58 at least one semiconductor die 14 directly onto a first side 20 of a substrate 12; after the at least one semiconductor die has been connected to the first side of the substrate, molding 62 a cap onto portions of both the first side 20 of the substrate 12 and lateral sides 24 of the at least one semiconductor die 14, the cap not extending above a top side 48 of the at least one semiconductor die; and connecting 60 fusible elements 16 to a second side 21 of the substrate. Molding the cap may comprise not molding the cap onto the top side of the at least one semiconductor die. Molding the cap may form the cap with a general square or rectangular shape. The method may further comprise subsequently connecting the fusible elements to a second substrate through through-mold vias (TMV) in a second mold cap 78, 98 on the second substrate 74, 94, where the second mold cap is located around at least one second semiconductor die 76, 96 on the second substrate.

It should be understood that the foregoing description is only illustrative of the invention. Various alternatives and modifications can be devised by those skilled in the art without departing from the invention. For example, features recited in the various dependent claims could be combined with each other in any suitable combination(s). In addition, features from different embodiments described above could be selectively combined into a new embodiment. Accordingly, the invention is intended to embrace all such alternatives, modifications and variances which fall within the scope of the appended claims.

1. A device comprising:
a substrate;
at least one semiconductor die on a first side of the substrate; and
a mold cap molded on portions of the first side of the substrate and on lateral sides of the at least one semiconductor die, where the mold cap is not molded onto a top side of the at least one semiconductor die.

2. A device as in claim 1 where the at least one semiconductor die comprises a plurality of semiconductor dies connected in a stack.

3. A device as in claim 2 where the semiconductor dies comprise through-silicon via (TSV) connections.

4. A device as in claim 1 where a top end of the mold cap is below the top side of the at least one semiconductor die.

5. A device as in claim where the mold cap has a general square or rectangular shape.

6. A device as in claim 1 where the mold cap has an inner facing surface located only around a side perimeter of the at least one semiconductor die.

7. A package comprising:
a first device comprising the device as in any one of the preceding claims; and
a second device comprising:
a second substrate;
at least one second semiconductor die on a first side of the second substrate; and
a second mold cap on the first side of the second substrate and on lateral sides of the at least one second semiconductor die,
where fusible elements of the first device are connected to the second device at the first side of the second substrate.

8. A package as in claim 7 where the fusible elements of the first device extend through through-mold vias (TMV) in the second mold cap.

9. A package as in claim 7 where the second mold cap is not molded onto a top side of the at least one second semiconductor die.

10. A package as in claim 7 where the at least one second semiconductor die comprises a plurality of second semiconductor dies connected in a stack.

11. A package as in claim 10 where the second semiconductor dies comprise through-silicon via (TSV) connections.

12. A package as in claim 7 where a top end of the second mold cap is below a top side of the at least one second semiconductor die.

13. A package as in claim 7 where a top end of the second mold cap is above a top side of the at least one second semiconductor die.

14. A package as in claim 7 where the second mold cap has a general square or rectangular shape.

15. A package as in claim 7 where the second mold cap has a top face, a bottom face and an inner facing surface located between the top and bottom faces and located only around a side perimeter of the at least one second semiconductor die.

16. A package as in claim 7 where the second substrate comprises silicon substrate, and the second mold cap is located over substantially the entire first side of the silicon substrate excluding an area of the silicon substrate having the at least one semiconductor die thereon.

17. A method comprising:
connecting at least one semiconductor die onto a first side of a substrate; and
after the at least one semiconductor die has been connected to the first side of the substrate, molding a cap onto portions of both the first side of the substrate and lateral sides of the at least one semiconductor die, the cap not extending above a top side of the at least one semiconductor die.

18. A method as in claim 17 where molding the cap does not mold the cap onto the top side of the at least one semiconductor die.

19. A method as in claim 17 where molding the cap forms the cap with a general square or rectangular shape.

20. A method as in claim 17 further comprising connecting fusible elements to a second side of the substrate and subsequently connecting the fusible elements to a second substrate through through-mold vias (TMV) in a second mold cap on the second substrate, where the second mold cap is located around at least one second semiconductor die on the second substrate.
